(19) United States
(12) Patent Application Publication
(10) Pub. No.: US 2018/0351058 A1
(43) Pub. Date: Dec. 6, 2018

(54) OPTOELECTRONIC COMPONENT AND METHOD OF PRODUCING AN OPTOELECTRONIC COMPONENT

(71) Applicant: OSRAM Opto Semiconductors GmbH, Regensburg (DE)

(72) Inventors: Ralf Mueller, Regensburg (DE); Ralf Staub, Regensburg (DE); Christian Ziereis, Tanjung Tokong (MY)

(21) Appl. No.: 15/991,271

(22) Filed: May 29, 2018

(30) Foreign Application Priority Data
Jun. 1, 2017 (DE) 10 2017 112 076.9

(51) Int. Cl. H01L 33/60; H01L 33/48; H01L 33/62; H01L 27/15; H01L 33/00

(52) U.S. Cl. CPC H01L 33/60; H01L 33/483; H01L 2933/0058; H01L 27/153; H01L 33/005; H01L 33/62

(57) ABSTRACT

An optoelectronic component includes a reflective material, wherein the reflective material includes a surface, at least one optoelectronic semiconductor chip is embedded into the reflective material such that at least a top side of the optoelectronic semiconductor chip, the top side being configured to emit electromagnetic radiation and is not covered by the reflective material, the surface of the reflective material is formed in a manner extending parallel to the top side of the optoelectronic semiconductor chip and facing away from an underside of the optoelectronic semiconductor chip, the surface of the reflective material includes a contrast region, and the reflective material is superficially removed in the contrast region.

### TECHNICAL FIELD

This disclosure relates to an optoelectronic component and a method of producing an optoelectronic component.

### BACKGROUND

Optoelectronic components that generate a defined light distribution are known. Bright-dark boundaries may be brought about, for example, by applying a luminous surface at the packaging edge. A further possibility consists of arranging additional structures, for example, a frame defining a bright-dark boundary. Furthermore, the use of black materials that generate defined light distributions is known.

There is nonetheless a need to provide an improved optoelectronic component and a method of producing an optoelectronic component.

### SUMMARY

We provide an optoelectronic component including a reflective material, wherein the reflective material includes a surface, at least one optoelectronic semiconductor chip is embedded into the reflective material such that at least a top side of the optoelectronic semiconductor chip, the top side being configured to emit electromagnetic radiation and is not covered by the reflective material, the surface of the reflective material is formed in a manner extending parallel to the top side of the optoelectronic semiconductor chip and facing away from an underside of the optoelectronic semiconductor chip, the surface of the reflective material includes a contrast region, and the reflective material is superficially removed in the contrast region.

We also provide a method of producing an optoelectronic component including providing at least one optoelectronic semiconductor chip including a top side configured to emit electromagnetic radiation; embedding the optoelectronic semiconductor chip into a reflective material, wherein the optoelectronic semiconductor chip is embedded into the reflective material such that at least the top side of the optoelectronic semiconductor chip is not covered by the reflective material, and a surface of the reflective material is formed parallel to the top side of the optoelectronic semiconductor chip and in a manner facing away from an underside of the optoelectronic semiconductor chip; and producing a contrast region by superficially removing the reflective material.

### BRIEF DESCRIPTION OF THE DRAWINGS

FIG. 1 shows a schematic side view of film assisted transfer molding.

FIG. 2 shows a schematic side view of an optoelectronic semiconductor chip embedded into a reflective material.

FIG. 3 shows a schematic side view of the optoelectronic component.

FIG. 4 shows a schematic plan view of the optoelectronic component.

### LIST OF REFERENCE SIGNS

10 Optoelectronic component
20 Carrier
21 Edges of the carrier
30 Optoelectronic semiconductor chip
31 Top side of the optoelectronic semiconductor chip
32 Underside of the optoelectronic semiconductor chip
33 Edges of the optoelectronic semiconductor chip
40 Reflective material
41 Surface of the reflective material
50 Mold tool
51 Upper part of the mold tool
52 Lower part of the mold tool
53 Mold cavity
54 Wall of the mold cavity
60 First film
61 Second film
70 Contrast region
71 Contours of the contrast region
80 Width of the contrast region
81 Distance between the contrast region and the edge of the optoelectronic semiconductor chip
82 Distance between the contrast region and the edge of the carrier

### DETAILED DESCRIPTION

Our optoelectronic component comprises a reflective material comprising a surface. At least one optoelectronic semiconductor chip is embedded into the reflective material such that at least a top side of the optoelectronic semiconductor chip, the top side configured to emit electromagnetic radiation, is not covered by the reflective material. The surface of the reflective material is formed in a manner extending parallel to the top side of the optoelectronic semiconductor chip and faces away from an underside of the optoelectronic semiconductor chip. The surface of the reflective material comprises a contrast region. The reflective material is superficially removed in the contrast region. Advantageously, on account of its contrast region the optoelectronic component makes it possible to generate a defined distribution of the electromagnetic radiation emitted by the optoelectronic semiconductor chip. In this case, the contrast region defines a bright-dark boundary since the contrast region is configured to absorb electromagnetic radiation, while electromagnetic radiation emitted by the optoelectronic semiconductor chip is reflected at the surface of the reflective material outside the contrast region.

The reflective material may be blackened in the contrast region. Advantageously, a blackening of the contrast region increases absorption of electromagnetic radiation.

The reflective material may comprise a silicone. Advantageously, a reflective material comprising silicone may be blackened. Furthermore, the performance of silicones is based on modification of their chemical structure, whereby a diversity of material properties are accessible. By way of example, optical properties may be set in a targeted manner. Moreover, silicones are suitable for insulation and may thus serve for protection against corrosion. Furthermore, an optoelectronic semiconductor chip embedded into a silicone is protected against mechanical vibrations.

A ratio of reflectivity between the non-blackened part of the surface of the reflective material and the contrast region may be at least 250:1, in particular at least 300:1. Advantageously, an optoelectronic component comprising such a ratio in respect of the reflectivity between the non-blackened part of the surface of the reflective material and the contrast region may generate defined distributions of the electromagnetic radiation emitted by the optoelectronic semiconductor chip.

The optoelectronic semiconductor chip may be arranged on a carrier. The carrier may be a leadframe, a printed circuit board or a ceramic. The optoelectronic semiconductor chip may be a light emitting diode chip.

The optoelectronic component may be an automobile headlight. Advantageously, an automobile headlight comprising a defined bright-dark boundary may be configured to emit electromagnetic radiation at a desired solid angle. This may serve, for example, to dazzle oncoming traffic as little as possible.

Our method of producing an optoelectronic component comprises the following method steps. At least one optoelectronic semiconductor chip comprising a top side configured to emit electromagnetic radiation is provided. The optoelectronic semiconductor chip is embedded into a reflective material, wherein the optoelectronic semiconductor chip is embedded into the reflective material such that at least the top side of the optoelectronic semiconductor chip is not covered by the reflective material. In this case, a surface of the reflective material is formed parallel to the top side of the optoelectronic semiconductor chip and in a manner facing away from an underside of the optoelectronic semiconductor chip. A contrast region is produced by superficially removing the reflective material. Advantageously, the method is distinguished by the fact that no further materials need be arranged on the surface of the reflective material for the purpose of producing a defined bright-dark boundary. Process and material costs are thus reduced.

The reflective material may be blackened during the process of producing the contrast region.

The optoelectronic semiconductor chip and the reflective material may be arranged on a carrier.

The contrast region may be produced by laser ablation. Advantageously, a contrast region that was produced by laser ablation comprises defined contours.

A UV laser may be used during laser ablation. Advantageously, with a UV laser enough power may be deposited on the surface of the reflective material to achieve formation of a plasma. As a result, the reflective material is superficially removed and blackened.

During production of the contrast region on the surface of the reflective material the blackening may be carried out by a carbonization of the reflective material. Advantageously, on account of the carbonization in the contrast region the reflective material comprises carbon black having a low reflectivity.

The reflective material may be arranged by film assisted transfer molding. Advantageously, film assisted transfer molding affords the possibility of embedding an optoelectronic semiconductor chip into the reflective material such that its top side remains free of the reflective material.

The above-described properties, features and advantages and the way in which they are achieved are clearer and more clearly understood in association with the following description of examples explained in greater detail in association with the drawings.

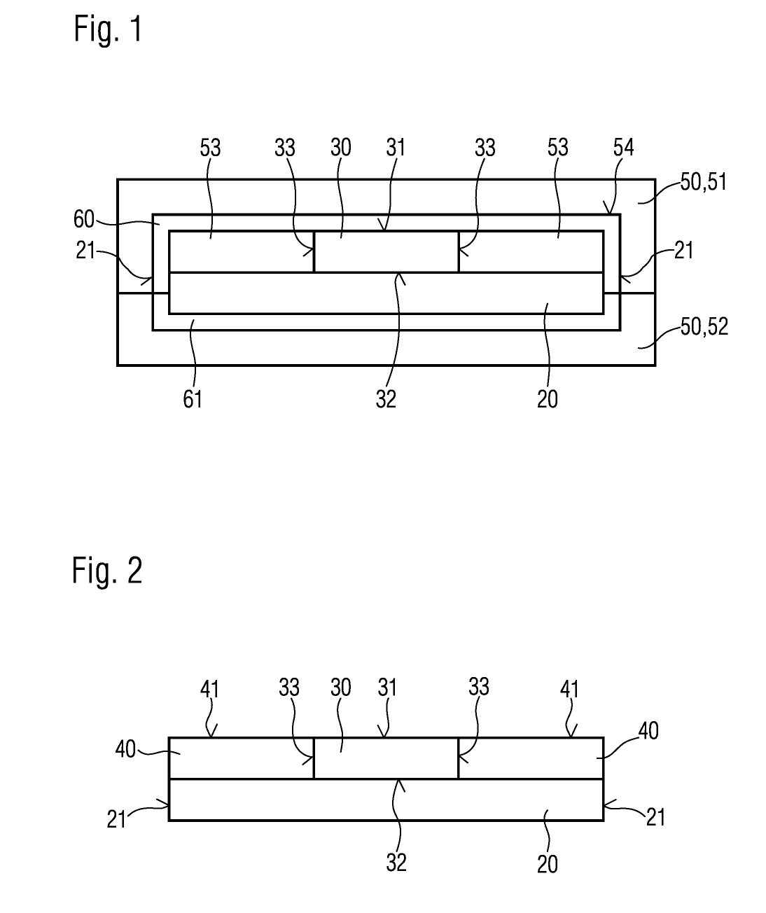

FIG. 1 shows, in a schematic side view, embedding of an optoelectronic semiconductor chip 30 into a reflective material 40 by film assisted transfer molding.

The optoelectronic semiconductor chip 30 comprises a top side 31, an underside 32 and edges 33. The optoelectronic semiconductor chip 30 is arranged by its underside 32 on a carrier 20. The top side 31 of the optoelectronic semiconductor chip 30 is configured to emit electromagnetic radiation. The optoelectronic semiconductor chip 30 may be a light emitting diode chip, for example.

In the illustration shown in FIG. 1, only one optoelectronic semiconductor chip 30 is arranged on the carrier 20. However, it is also possible for a plurality of optoelectronic semiconductor chips 30 to be arranged on the carrier 20. The carrier 20 may be, for example, a leadframe, a printed circuit board or a ceramic. However, the carrier 20 may also be some other substrate. The carrier 20 comprises edges 21.

For the purpose of embedding the optoelectronic semiconductor chip 30 into the reflective material 40, a mold tool 50 is used in film assisted transfer molding. The mold tool 50 comprises an upper part 51 and a lower part 52. The upper part 51 and the lower part 52 of the mold tool 50 enclose a mold cavity 53. The mold cavity 53 comprises a wall 54. At the upper part 51 of the mold tool 50, a first film 60 is arranged at the wall 54 of the mold cavity 53. At the lower part 52 of the mold tool 50, a second film 61 is arranged at the wall 54 of the mold cavity 53. The first and second films 60, 61 may be Teflon films, for example.

The reflective material 40 is arranged within the mold cavity 53. The reflective material 40 may comprise a silicone, for example. The top side 31 of the optoelectronic semiconductor chip 30 is pressed against the film 60 during the process of arranging the reflective material 40 so that the top side 31 of the optoelectronic semiconductor chip 30 remains free of the reflective material 40.

FIG. 2 shows, in a schematic side view, the optoelectronic semiconductor chip 30 embedded into the reflective material 40 after removal from the mold tool 50.

The reflective material 40 comprises a surface 41 formed in a manner extending parallel to the top side 31 of the optoelectronic semiconductor chip 30. Furthermore, the surface 41 of the reflective material 40 faces away from the underside 32 of the optoelectronic semiconductor chip 30. The top side 31 of the optoelectronic semiconductor chip 30, the top side being configured to emit electromagnetic radiation, is not covered by the reflective material 40.

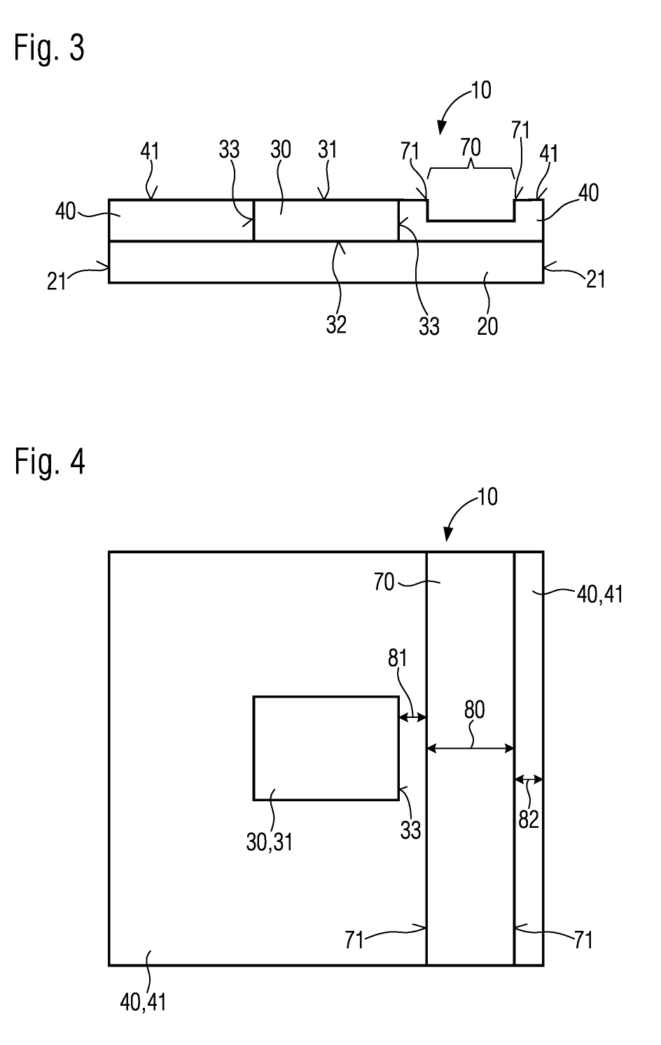

FIG. 3 shows, in a schematic side view, a completed optoelectronic component 10 after a processing step succeeding the illustration in FIG. 2. The optoelectronic component 10 comprises a contrast region 70. The reflective material 40 is superficially removed in the contrast region 70. In addition, the reflective material 40 may be blackened in the contrast region 70.

The contrast region 70 may be produced by laser ablation, for example. Laser ablation is understood to mean bombardment of a surface with pulsed laser radiation. With the use of laser radiation comprising a high power density, a rapid heating of the surface 41 of the reflective material 40 takes place. A feature of laser ablation is that a plasma is formed at the surface 41 of the reflective material 40 on account of an ionization of the reflective material 40. In this case, the reflective material 40 is superficially removed. The ionization of the reflective material 40 may be carried out thermally, by the incident laser light or by electron impact ionization. Typically, a few micrometers of the surface 41 of the reflective material 40 are removed during the laser ablation.

The blackening of the reflective material 40 may be carried out by carbonization of the reflective material 40. As a result, the reflective material 40 comprises carbon black in the contrast region 70. As a result of carbonization of the reflective material 40, a reduced reflectivity of the reflective material 40 is present in the contrast region 70. The contrast region 70 may also be produced by some other method suitable for blackening the reflective material 40. By way of example, the surface 41 of the reflective material 40 may also be irradiated with electrons or ions. By way of example, a wet-chemical blackening of the surface 41 of the reflective material 40 for the purpose of producing the contrast region 70 is also possible, wherein the regions of the surface 41 of the reflective material 40 which are not to be blackened might be passivated beforehand.

A UV laser may be used, for example, to achieve the power densities required for the laser ablation. One advantage of producing a contrast region 70 by laser ablation is that a good spatial resolution may be achieved. As a result, the contrast region 70 comprises defined contours 71. This fosters production of defined distributions of the electromagnetic radiation emitted by the optoelectronic semiconductor chip 30.

A ratio of the reflectivity between the non-blackened part of the surface 41 of the reflective material 40 and the contrast region 70 may be at least 250:1, in particular at least 300:1.

FIG. 4 shows a schematic illustration of the optoelectronic component 10 in plan view.

In the example illustrated, the optoelectronic component 10 comprises only one optoelectronic semiconductor chip 30. However, a multiplicity of optoelectronic semiconductor chips 30 may also be embedded into the reflective material 40. The shape of the optoelectronic semiconductor chip 30 may also deviate from the rectangular shape shown in FIG. 4.

Furthermore, the optoelectronic semiconductor chip 30 is arranged centrally on the carrier 20 in the example illustrated. This, too, is not absolutely necessary. The optoelectronic semiconductor chip 30 might also be arranged nearer to an edge 21 of the carrier 20. The central arrangement of the optoelectronic semiconductor chip 30 on the carrier 20 has the advantage, however, that an undesired lateral emission of electromagnetic radiation may be suppressed. A lateral emission of electromagnetic radiation is present, for example, if the optoelectronic semiconductor chip 30, for the purpose of creating a bright-dark boundary, is arranged as near as possible to an edge 21 of the carrier 20. Producing a contrast region 70 thus has the advantage that the optoelectronic semiconductor chip 30 may also be arranged centrally on the carrier 20, as a result of which an undesired lateral emission of electromagnetic radiation may be prevented.

In the example illustrated, the optoelectronic component 10 comprises a contrast region 70 formed in a strip-shaped fashion. However, this is not absolutely necessary. The optoelectronic component 10 may also comprise a plurality of contrast regions 70. By way of example, the optoelectronic semiconductor chip 30 may be surrounded by two, three or, for example, four contrast regions 70 formed in a strip-shaped fashion. The shape of the contrast region 70 may also deviate from the shape illustrated in FIG. 4. In this case, any arbitrary shape is possible. By way of example, the contrast region 70 may be present in the form of triangles. It would also be possible for the contrast region 70 to be formed on the entire surface 41 of the reflective material 40.

In the example shown in FIG. 4, the contrast region 70 comprises a width 80 between the contours 71, a distance 81 with respect to the edge 33 of the optoelectronic semiconductor chip 30 that faces the contrast region 70, and a distance 82 with respect to an edge 21 of the carrier 20 that faces the contrast region 70 and is formed parallel thereto. Both the width 80 of the contrast region 70 and the distances 81 and 82 may deviate from the example illustrated in FIG. 4. By way of example, the contrast region 70 may be formed from the edge 33 of the optoelectronic semiconductor chip 30 as far as the edge 21 of the carrier 20. In this case, the contrast region 70 comprises no distance 81 with respect to the edge 33 of the optoelectronic semiconductor chip 30 and no distance 82 with respect to the edge 21 of the carrier 20. The exact distances 80, 81, 82 are dependent on the field of application in which the optoelectronic component 10 is intended to be used, and may be chosen freely depending on the design. In general, the extent of a contrast region 70 will be of the order of magnitude of the lateral extent of one optoelectronic semiconductor chip 30 or of a plurality of optoelectronic semiconductor chips 30. Consequently, a distance 80, 81, 82 may be, for example, a few μm but also a few mm.

The optoelectronic component 10 may be an automobile headlight, for example. In this case, the contrast region 70 may be configured to generate a defined light distribution. By way of example, the contrast region 70 of the automobile headlight may be configured to dazzle oncoming traffic as little as possible.

Our components and methods have been illustrated and described in greater detail on the basis of preferred examples. Nevertheless, this disclosure is not restricted to the examples disclosed. Rather, other variations may be derived therefrom by those skilled in the art, without departing from the scope of protection of the appended claims.

This application claims priority of DE 10 2017 112 076.9, the subject matter of which is incorporated herein by reference.

1-15. (canceled)

16. An optoelectronic component comprising a reflective material,
wherein the reflective material comprises a surface,
at least one optoelectronic semiconductor chip is embedded into the reflective material such that at least a top side of the optoelectronic semiconductor chip, said top side being configured to emit electromagnetic radiation and is not covered by the reflective material,
the surface of the reflective material is formed in a manner extending parallel to the top side of the optoelectronic semiconductor chip and facing away from an underside of the optoelectronic semiconductor chip,
the surface of the reflective material comprises a contrast region, and
the reflective material is superficially removed in the contrast region.

17. The optoelectronic component according to claim 16, wherein the reflective material is blackened in the contrast region.

18. The optoelectronic component according to claim 16, wherein the reflective material comprises a silicone.

19. The optoelectronic component according to claim 17, wherein a ratio of reflectivity between the non-blackened part of the surface of the reflective material and the contrast region is at least 250:1.

20. The optoelectronic component according to claim 16, wherein the optoelectronic semiconductor chip is arranged on a carrier.

21. The optoelectronic component according to claim 20, wherein the carrier is a leadframe, a printed circuit board or a ceramic.

22. The optoelectronic component according to claim 16, wherein the optoelectronic semiconductor chip is a light emitting diode chip.

23. The optoelectronic component according to claim 16, wherein the optoelectronic component is an automobile headlight.

24. A method of producing an optoelectronic component comprising:
providing at least one optoelectronic semiconductor chip comprising a top side configured to emit electromagnetic radiation;
embedding the optoelectronic semiconductor chip into a reflective material, wherein the optoelectronic semiconductor chip is embedded into the reflective material such that at least the top side of the optoelectronic semiconductor chip is not covered by the reflective material, and a surface of the reflective material is formed parallel to the top side of the optoelectronic semiconductor chip and in a manner facing away from an underside of the optoelectronic semiconductor chip; and
producing a contrast region by superficially removing the reflective material.

25. The method according to claim 24, wherein the reflective material is blackened during the process of producing the contrast region.

26. The method according to claim 24, wherein the optoelectronic semiconductor chip and the reflective material are arranged on a carrier.

27. The method according to claim 24, wherein the contrast region is produced by laser ablation.

28. The method according to claim 27, wherein a UV laser is used during the laser ablation.

29. The method according to claim 25, wherein, during production of the contrast region on the surface of the reflective material, the blackening is carried out by a carbonization of the reflective material.

30. The method according to claim 24, wherein the reflective material is arranged by film assisted transfer molding.
